(19) United States
(12) Patent Application Publication
(10) Pub. No.: US 2020/0234952 A1
(43) Pub. Date: Jul. 23, 2020

(54) SEMICONDUCTOR DEVICES HAVING HETEROJUNCTIONS OF AN ALUMINUM GALLIUM NITRIDE TERNARY ALLOY LAYER AND A SECOND III NITRIDE TERNARY ALLOY LAYER

(71) Applicant: KING ABDULLAH UNIVERSITY OF SCIENCE AND TECHNOLOGY, Thuwal (SA)

(72) Inventors: Xiaohang LI, Thuwal (SA); Kaikai LIU, Thuwal (SA)

(21) Appl. No.: 16/839,603

(22) Filed: Apr. 3, 2020

Related U.S. Application Data
(63) Continuation of application No. PCT/IB2018/057852, filed on Oct. 10, 2018.
Application No. PCT/IB2018/057852 is a continuation of application No. PCT/IB2018/057853, filed on Oct. 10, 2018.
Application No. PCT/IB2018/057853 is a continuation of application No. PCT/IB2018/057854, filed on Oct. 10, 2018.
Application No. PCT/IB2018/057854 is a continuation of application No. PCT/IB2018/057855, filed on Oct. 10, 2018.
Application No. PCT/IB2018/057855 is a continuation of application No. PCT/IB2018/057856, filed on Oct. 10, 2018.
(60) Provisional application No. 62/594,767, filed on Dec. 5, 2017.
(60) Provisional application No. 62/594,774, filed on Dec. 5, 2017.
(60) Provisional application No. 62/594,330, filed on Dec. 4, 2017.
(60) Provisional application No. 62/594,389, filed on Dec. 4, 2017.
(60) Provisional application No. 62/594,391, filed on Dec. 4, 2017.
(60) Provisional application No. 62/576,246, filed on Oct. 24, 2017.
(60) Provisional application No. 62/570,798, filed on Oct. 11, 2017.
(60) Provisional application No. 62/594,767, filed on Dec. 5, 2017.
(60) Provisional application No. 62/594,774, filed on Dec. 5, 2017.
(60) Provisional application No. 62/594,330, filed on Dec. 4, 2017.
(60) Provisional application No. 62/594,389, filed on Dec. 4, 2017.
(60) Provisional application No. 62/594,391, filed on Dec. 4, 2017.
(60) Provisional application No. 62/576,246, filed on Oct. 24, 2017.
(60) Provisional application No. 62/570,798, filed on Oct. 11, 2017.
(60) Provisional application No. 62/594,767, filed on Dec. 5, 2017.
(60) Provisional application No. 62/594,774, filed on Dec. 5, 2017.
(60) Provisional application No. 62/594,330, filed on Dec. 4, 2017.
(60) Provisional application No. 62/594,389, filed on Dec. 4, 2017.
(60) Provisional application No. 62/594,391, filed on Dec. 4, 2017.
(60) Provisional application No. 62/576,246, filed on Oct. 24, 2017.
(60) Provisional application No. 62/570,798, filed on Oct. 11, 2017.
(60) Provisional application No. 62/594,767, filed on Dec. 5, 2017.
(60) Provisional application No. 62/594,774, filed on Dec. 5, 2017.
(60) Provisional application No. 62/594,330, filed on Dec. 4, 2017.
(60) Provisional application No. 62/594,389, filed on Dec. 4, 2017.
(60) Provisional application No. 62/594,391, filed on Dec. 4, 2017.
(60) Provisional application No. 62/576,246, filed on Oct. 24, 2017.
(60) Provisional application No. 62/570,798, filed on Oct. 11, 2017.
(60) Provisional application No. 62/594,767, filed on Dec. 5, 2017.
(60) Provisional application No. 62/594,774, filed on Dec. 5, 2017.
(60) Provisional application No. 62/594,330, filed on Dec. 4, 2017.
(60) Provisional application No. 62/594,389, filed on Dec. 4, 2017.
(60) Provisional application No. 62/594,391, filed on Dec. 4, 2017.
(60) Provisional application No. 62/576,246, filed on Oct. 24, 2017.
(60) Provisional application No. 62/570,798, filed on Oct. 11, 2017.

(51) Int. Cl. H01L 21/02; H01L 29/20; H01L 29/778

(52) U.S. Cl. CPC H01L 21/02389; H01L 21/02458; H01L 29/7783; H01L 29/2003; H01L 21/0242; H01L 21/0254

(57) ABSTRACT

A method for forming a semiconductor device having a heterojunction of a first III-nitride ternary alloy layer arranged on a second III-nitride ternary alloy layer is provided. A range of concentrations of III-nitride elements for the first and second III-nitride ternary alloy layers is determined so that the absolute value of the polarization difference at the interface of the heterojunction of the first and second III-nitride ternary alloy layers is less than or equal to 0.007 C/m² or greater than or equal to 0.04 C/m². Specific concentrations of III-nitride elements for the first and second III-nitride ternary alloy layers are selected from the determined range of concentrations so that the absolute value of the polarization difference at the interface of the heterojunction of the first and second III-nitride ternary alloy layers is less than or equal to 0.007 C/m² or greater than or equal to 0.04 C/m². The semiconductor device is formed using the selected specific concentrations of III-nitride elements for the first and second III-nitride ternary alloy layers. The first and second III-nitride ternary alloy layers have a Wurtzite crystal structure. The first III-nitride ternary alloy layer is AlGaN and the second III-nitride ternary alloy layer is InGaN, InAlN, BAlN, or BGaN, or the first III-nitride ternary alloy layer is InGaN and the second III-nitride ternary alloy layer is AlGaN, InAlN, BAlN, or BGaN, or first III-nitride ternary alloy layer is InAlN and the second III-nitride ternary alloy layer is InGaN, AlGaN, BAlN, or BGaN, or the first III-nitride ternary alloy layer is BAlN and the second III-nitride ternary alloy layer is InGaN, InAlN, AlGaN, or BGaN, or first III-nitride ternary alloy layer is BGaN and the second III-nitride ternary alloy layer is InGaN, InAlN, BAlN, or AlGaN.

### CROSS-REFERENCE TO RELATED APPLICATIONS

This application is a U.S. Continuation of International Application No. PCT/IB2018/057852, filed on Oct. 10, 2018, International Application No. PCT/IB2018/057853, filed on Oct. 10, 2018, International Application No. PCT/IB2018/057854, filed on Oct. 10, 2018, International Application No. PCT/IB2018/057855, filed on Oct. 10, 2018, International Application No. PCT/IB2018/057856, filed on Oct. 10, 2018, all which claim priority to U.S. Provisional Patent Application No. 62/570,798, filed on Oct. 11, 2017, entitled “BORON III NITRIDE HETEROJUNCTIONS WITH ZERO TO LARGE HETEROINTERFACE POLARIZATIONS,” U.S. Provisional Patent Application No. 62/576,246, filed on Oct. 24, 2017, entitled “III-NITRIDE SEMICONDUCTOR HETEROSTRUCTURES WITH ZERO TO LARGE HETEROINTERFACE POLARIZATION,” U.S. Provisional Patent Application No. 62/594,330, filed on Dec. 4, 2017, entitled “POLARIZATION EFFECT OF InGaN/AlInN HETEROJUNCTIONS STRAINED ON GaN,” U.S. Provisional Patent Application No. 62/594,389, filed on Dec. 4, 2017, entitled “POLARIZATION EFFECT OF GaAlN/AlInN HETEROJUNCTIONS STRAINED ON AlN,” U.S. Provisional Patent Application No. 62/594,391, filed on Dec. 4, 2017, entitled “POLARIZATION EFFECT OF AlGaN/InGaN HETEROJUNCTIONS STRAINED ON GaN,” U.S. Provisional Patent Application No. 62/594,767, filed on Dec. 5, 2017, entitled “POLARIZATION EFFECT OF AlGaN/BGaN HETEROJUNCTIONS STRAINED ON GaN,” and U.S. Provisional Patent Application No. 62/594,774, filed on Dec. 5, 2017, entitled “POLARIZATION EFFECT OF AlGaN/AlInN HETEROJUNCTIONS STRAINED ON AlN,” the disclosures of which are incorporated herein by reference in their entirety.

### BACKGROUND

### Technical Field

Embodiments of the disclosed subject matter generally relate to semiconductor devices having heterojunctions of wurtzite III-nitride ternary alloys in which the heterojunction exhibits either small or large polarization differences based on compositions of the elements forming the two wurtzite III-nitride ternary alloy layers forming the heterojunction.

### Discussion of the Background

Wurtzite (WZ) III-nitride semiconductors and their alloys are particularly advantageous for use in optoelectronic devices, such as visible and ultraviolet light emitting diodes (LEDs), laser diodes, and high-power devices, such as high electron mobility transistors (HEMTs). Due to the asymmetry of the wurtzite structure, the III-nitrides and their heterojunctions can exhibit strong spontaneous polarization (SP) and piezoelectric (PZ) polarization, which can greatly influence the operation of the semiconductor device. For example, LEDs and laser diodes can have reduced radiative recombination rates and shifts in emission wavelength due to the quantum-confined Stark effect (QCSE) caused by the internal polarization field in the quantum well (QW). Thus, for these types of devices, a smaller polarization difference at the interface of the heterojunction could advantageously minimize or eliminate the quantum-confined Stark effect. In contrast, high electron mobility transistors (HEMTs) require a high polarization difference at the interface of the heterojunction to produce strong carrier confinement and formation of two-dimensional electron gas (2DEG).

The polarization difference at the interface of the heterojunction of wurtzite III-nitride semiconductors is currently calculated using polarization constants of wurtzite III-nitride alloys that may not be accurate. Specifically, the conventional polarization constants of wurtzite III-nitride ternary alloys are based on linear interpolation of the binary material constants (i.e., of boron nitride (BN), aluminum nitride (AlN), gallium nitride (GaN), and indium nitride (InN)). However, there could be considerable nonlinearity in the spontaneous polarization and piezoelectric polarization of wurtzite III-nitride ternary alloys (e.g., AlGaN, InGaN, InAlN, BAlN, and BGaN) versus the respective binary material composition.

Thus, it would be desirable to provide methods for accurately determining spontaneous polarization and piezoelectric polarization of wurtzite III-nitride ternary alloys, as well as using these determinations to form semiconductor devices comprising wurtzite III-nitride ternary alloys that are optimized to have either a high or low polarization difference at the interface of the heterojunction, depending upon the intended application of the semiconductor devices.

### SUMMARY

According to an embodiment, there is a method for forming a semiconductor device comprising a heterojunction of a first III-nitride ternary alloy layer arranged on a second III-nitride ternary alloy layer. Initially, it is determined that an absolute value of a polarization difference at an interface of the heterojunction of the first and second III-nitride ternary alloy layers should be less than or equal to 0.007 C/m² or greater than or equal to 0.04 C/m². A range of concentrations of III-nitride elements for the first and second III-nitride ternary alloy layers is determined so that the absolute value of the polarization difference at the interface of the heterojunction of the first and second III-nitride ternary alloy layers is less than or equal to 0.007 C/m² or greater than or equal to 0.04 C/m². Specific concentrations of III-nitride elements for the first and second III-nitride ternary alloy layers are selected from the determined range of concentrations so that the absolute value of the polarization difference at the interface of the heterojunction of the first and second III-nitride ternary alloy layers is less than or equal to 0.007 C/m² or greater than or equal to 0.04 C/m². The semiconductor device comprising the heterojunction is formed using the selected specific concentrations of III-nitride elements for the first and second III-nitride ternary alloy layers. The first and second III-nitride ternary alloy layers have a wurtzite crystal structure. In one embodiment, the first III-nitride ternary alloy layer is aluminum gallium nitride (AlGaN) and the second III-nitride ternary alloy layer is indium gallium nitride (InGaN), indium aluminum nitride (InAlN), boron aluminum nitride (BAlN), or boron gallium nitride (BGaN). In another embodiment, the first III-nitride ternary alloy layer is indium gallium nitride (InGaN) and the second III-nitride ternary alloy layer is aluminum gallium nitride (AlGaN), indium aluminum nitride (InAlN), boron aluminum nitride (BAlN), or boron gallium nitride (BGaN). In a further embodiment, the first III-nitride ternary alloy layer is indium aluminum nitride (InAlN) and the second III-nitride ternary alloy layer is indium gallium nitride (InGaN), aluminum gallium nitride (AlGaN), boron aluminum nitride (BAlN), or boron gallium nitride (BGaN). In yet another embodiment, the first III-nitride ternary alloy layer is boron aluminum nitride (BAlN) and the second III-nitride ternary alloy layer is indium gallium nitride (InGaN), indium aluminum nitride (InAlN), aluminum gallium nitride (AlGaN), or boron gallium nitride (BGaN). In a further embodiment, the first III-nitride ternary alloy layer is boron gallium nitride (BGaN) and the second III-nitride ternary alloy layer is indium gallium nitride (InGaN), indium aluminum nitride (InAlN), boron aluminum nitride (BAlN), or aluminum gallium nitride (AlGaN).

According to another embodiment, there is a semiconductor device, comprising a heterojunction comprising a first III-nitride ternary alloy layer arranged on a second III-nitride ternary alloy layer. An absolute value of a polarization difference at an interface of the heterojunction of the first and second III-nitride ternary alloy layers is less than or equal to 0.007 C/m² or greater than or equal to 0.04 C/m² based on concentrations of III-nitride elements of the first and second III-nitride ternary alloy layers. The first and second III-nitride ternary alloy layers have a wurtzite crystal structure. In one embodiment, the first III-nitride ternary alloy layer is aluminum gallium nitride (AlGaN) and the second III-nitride ternary alloy layer is indium gallium nitride (InGaN), indium aluminum nitride (InAlN), boron aluminum nitride (BAlN), or boron gallium nitride (BGaN). In another embodiment, the first III-nitride ternary alloy layer is indium gallium nitride (InGaN) and the second III-nitride ternary alloy layer is aluminum gallium nitride (AlGaN), indium aluminum nitride (InAlN), boron aluminum nitride (BAlN), or boron gallium nitride (BGaN). In a further embodiment, the first III-nitride ternary alloy layer is indium aluminum nitride (InAlN) and the second III-nitride ternary alloy layer is indium gallium nitride (InGaN), aluminum gallium nitride (AlGaN), boron aluminum nitride (BAlN), or boron gallium nitride (BGaN). In yet another embodiment, the first III-nitride ternary alloy layer is boron aluminum nitride (BAlN) and the second III-nitride ternary alloy layer is indium gallium nitride (InGaN), indium aluminum nitride (InAlN), aluminum gallium nitride (AlGaN), or boron gallium nitride (BGaN). In a further embodiment, the first III-nitride ternary alloy layer is boron gallium nitride (BGaN) and the second III-nitride ternary alloy layer is indium gallium nitride (InGaN), indium aluminum nitride (InAlN), boron aluminum nitride (BAlN), or aluminum gallium nitride (AlGaN).

According to a further embodiment, there is a method for forming a semiconductor device comprising a heterojunction of a first III-nitride ternary alloy layer arranged on a second III-nitride ternary alloy layer on a substrate. Initially, it is determined that an absolute value of a polarization difference at an interface of the heterojunction of the first and second III-nitride ternary alloy layers should be less than or equal to 0.007 C/m² or greater than or equal to 0.04 C/m². A range of concentrations of III-nitride elements for the first and second III-nitride ternary alloy layers and a lattice constant of the substrate are determined so that the absolute value of the polarization difference at the interface of the heterojunction of the first and second III-nitride ternary alloy layers is less than or equal to 0.007 C/m² or greater than or equal to 0.04 C/m². Specific concentrations of III-nitride elements for the first and second III-nitride ternary alloy layers are selected from the determined range of concentrations and a specific substrate is selected so that the absolute value of the polarization difference at the interface of the heterojunction of the first and second III-nitride ternary alloy layers is less than or equal to 0.007 C/m² or greater than or equal to 0.04 C/m². The semiconductor device comprising the heterojunction on the substrate is formed using the selected specific concentrations of III-nitride elements for the first and second III-nitride ternary alloy layers and the specific substrate. The first and second III-nitride ternary alloy layers have a wurtzite crystal structure. In one embodiment, the first III-nitride ternary alloy layer is aluminum gallium nitride (AlGaN) and the second III-nitride ternary alloy layer is indium gallium nitride (InGaN), indium aluminum nitride (InAlN), boron aluminum nitride (BAlN), or boron gallium nitride (BGaN). In another embodiment, the first III-nitride ternary alloy layer is indium gallium nitride (InGaN) and the second III-nitride ternary alloy layer is aluminum gallium nitride (AlGaN), indium aluminum nitride (InAlN), boron aluminum nitride (BAlN), or boron gallium nitride (BGaN). In a further embodiment, the first III-nitride ternary alloy layer is indium aluminum nitride (InAlN) and the second III-nitride ternary alloy layer is indium gallium nitride (InGaN), aluminum gallium nitride (AlGaN), boron aluminum nitride (BAlN), or boron gallium nitride (BGaN). In yet another embodiment, the first III-nitride ternary alloy layer is boron aluminum nitride (BAlN) and the second III-nitride ternary alloy layer is indium gallium nitride (InGaN), indium aluminum nitride (InAlN), aluminum gallium nitride (AlGaN), or boron gallium nitride (BGaN). In a further embodiment, the first III-nitride ternary alloy layer is boron gallium nitride (BGaN) and the second III-nitride ternary alloy layer is indium gallium nitride (InGaN), indium aluminum nitride (InAlN), boron aluminum nitride (BAlN), or aluminum gallium nitride (AlGaN).

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is a flowchart of a method of forming a semiconductor device comprising a heterojunction of two wurtzite III-nitride ternary alloy layers according to embodiments;

FIGS. 2A-2E are schematic diagrams of semiconductor devices comprising a heterojunction of two wurtzite III-nitride ternary alloy layers according to embodiments;

FIG. 3 is a flowchart of a method of forming a semiconductor device comprising a heterojunction of two wurtzite III-nitride ternary alloy layers on a substrate according to embodiments;

FIGS. 4A-4E are schematic diagrams of semiconductor devices comprising a heterojunction of two wurtzite III-nitride ternary alloy layers on a substrate according to embodiments;

FIG. 5A is a graph of calculated lattice constants versus boron composition of wurtzite aluminum gallium nitride (AlGaN) according to embodiments;

FIG. 5B is a graph of calculated lattice constants versus boron composition of wurtzite indium gallium nitride (InGaN) according to embodiments;

FIG. 5C is a graph of calculated lattice constants versus aluminum composition of wurtzite indium aluminum nitride (InAlN) according to embodiments;

FIG. 5D is a graph of calculated lattice constants versus indium composition of wurtzite boron aluminum nitride (BAlN) according to embodiments; and

FIG. 5E is a graph of calculated lattice constants versus indium composition of wurtzite boron gallium nitride (BGaN) according to embodiments.

### DETAILED DESCRIPTION

The following description of the exemplary embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of wurtzite III-nitride ternary alloys.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

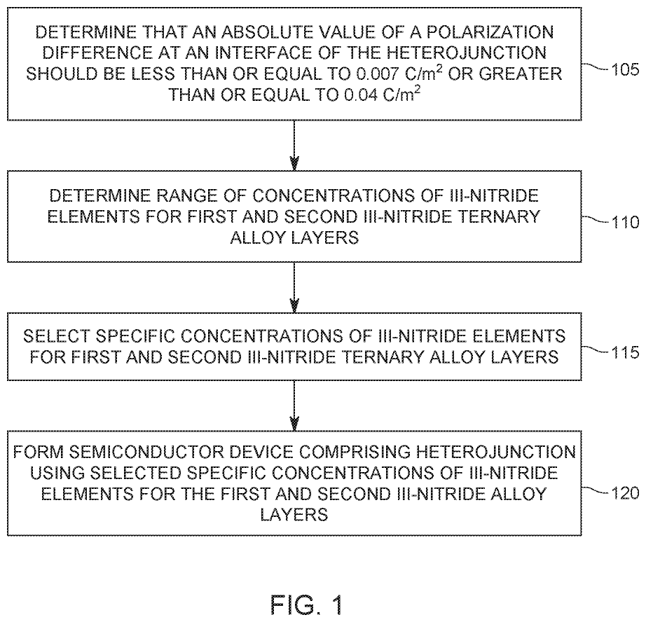

FIG. 1 is a flowchart of a method for forming a semiconductor device comprising a heterojunction of a first III-nitride ternary alloy layer arranged on a second III-nitride ternary alloy layer according to embodiments. Initially, it is determined that an absolute value of a polarization difference at an interface of the heterojunction of the first and second III-nitride ternary alloy layers should be less than or equal to 0.007 C/m² or greater than or equal to 0.04 C/m² (step 105). A range of concentrations of III-nitride elements for the first and second III-nitride ternary alloy layers are determined so that the absolute value of the polarization difference at the interface of the heterojunction of the first and second III-nitride ternary alloy layers is less than or equal to 0.007 C/m² or greater than or equal to 0.04 C/m² (step 110).

Specific concentrations of III-nitride elements for the first and second III-nitride ternary alloy layers are selected from the determined range of concentrations so that the absolute value of the polarization difference at the interface of the heterojunction of the first and second III-nitride ternary alloy layers is less than or equal to 0.007 C/m² or greater than or equal to 0.04 C/m² (step 115). Finally, the semiconductor device comprising the heterojunction is formed using the selected specific concentrations of III-nitride elements for the first and second III-nitride ternary alloy layers (step 120). The first and second III-nitride ternary alloy layers have a wurtzite crystal structure. In one embodiment, the first III-nitride ternary alloy layer is aluminum gallium nitride (AlGaN) and the second III-nitride ternary alloy layer is indium gallium nitride (InGaN), indium aluminum nitride (InAlN), boron aluminum nitride (BAlN), or boron gallium nitride (BGaN). In another embodiment, the first III-nitride ternary alloy layer is indium gallium nitride (InGaN) and the second III-nitride ternary alloy layer is aluminum gallium nitride (AlGaN), indium aluminum nitride (InAlN), boron aluminum nitride (BAlN), or boron gallium nitride (BGaN). In a further embodiment, the first III-nitride ternary alloy layer is indium aluminum nitride (InAlN) and the second III-nitride ternary alloy layer is indium gallium nitride (InGaN), aluminum gallium nitride (AlGaN), boron aluminum nitride (BAlN), or boron gallium nitride (BGaN). In yet another embodiment, the first III-nitride ternary alloy layer is boron aluminum nitride (BAlN) and the second III-nitride ternary alloy layer is indium gallium nitride (InGaN), indium aluminum nitride (InAlN), aluminum gallium nitride (AlGaN), or boron gallium nitride (BGaN). In a further embodiment, the first III-nitride ternary alloy layer is boron gallium nitride (BGaN) and the second III-nitride ternary alloy layer is indium gallium nitride (InGaN), indium aluminum nitride (InAlN), boron aluminum nitride (BAlN), or aluminum gallium nitride (AlGaN). The formation of the layers can be performed using any technique, including, but not limited to, metalorganic chemical vapor deposition, molecular beam epitaxy, and high temperature post-deposition annealing.

The absolute value of the polarization difference at the interface between the first and second III-nitride ternary alloy layers being less than or equal to 0.007 C/m² is advantageous for certain semiconductor devices, such as optoelectronic devices, including LEDs and laser diodes. On the other hand, the absolute value of the polarization difference at the interface between the first and second III-nitride ternary alloy layers being greater than or equal to 0.04 C/m² is advantageous for certain semiconductor devices, such as high electron mobility transistors (HEMTs).

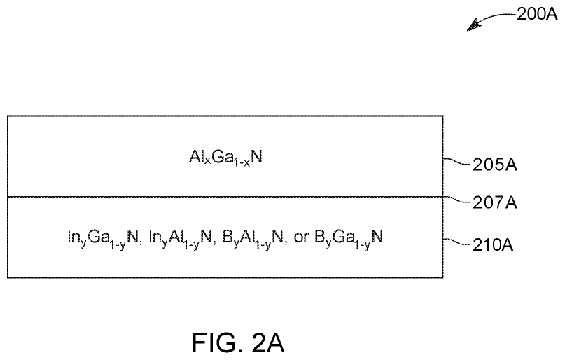

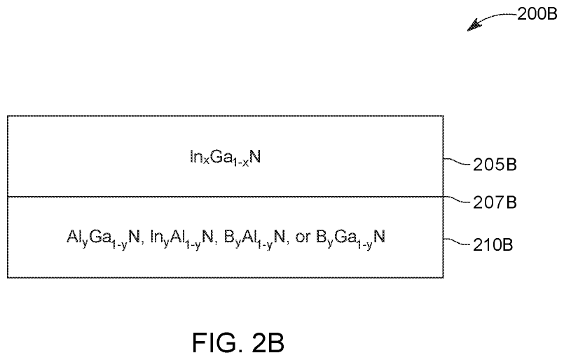

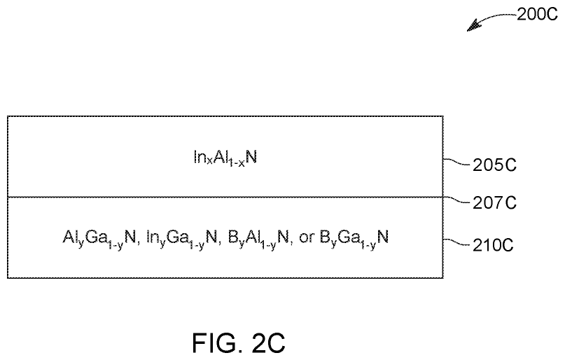

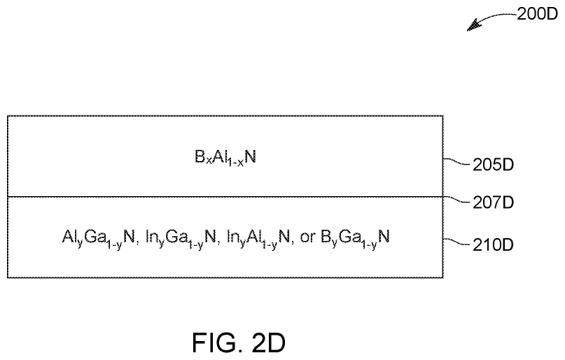

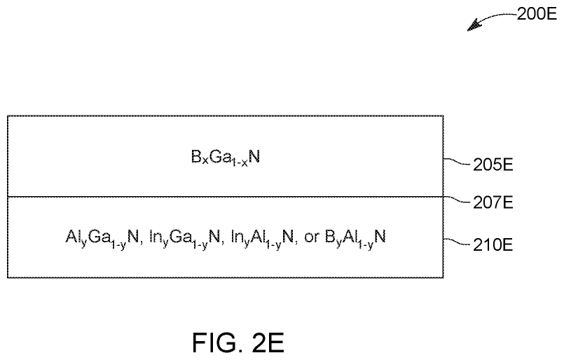

Schematic diagrams of semiconductor devices comprising a heterojunction of two wurtzite III-nitride ternary alloy layers according to the method of FIG. 1 are illustrated in FIGS. 2A-2E. As illustrated, the semiconductor device 200A-200E includes a heterojunction comprising a first III-nitride ternary alloy layer 205A-205E arranged on a second III-nitride ternary alloy layer 210A-210E. An absolute value of a polarization difference at an interface 207A-207E of the heterojunction of the first 205A-205E and second 210A-210E III-nitride ternary alloy layers is less than or equal to 0.007 C/m² or greater than or equal to 0.04 C/m² based on concentrations of III-nitride elements of the first 205A-205E and second 210A-210E III-nitride ternary alloy layers. The first 205A-205E and second 210A-210E III-nitride ternary alloy layers have a wurtzite crystal structure. In the embodiment illustrated in FIG. 2A, the first III-nitride ternary alloy layer 205A is aluminum gallium nitride (AlGaN) and the second III-nitride ternary alloy layer 210A is indium gallium nitride (InGaN), indium aluminum nitride (InAlN), boron aluminum nitride (BAlN), or boron gallium nitride (BGaN). In the embodiment illustrated in FIG. 2B, the first III-nitride ternary alloy layer 205B is indium gallium nitride (InGaN) and the second III-nitride ternary alloy layer 210B is aluminum gallium nitride (AlGaN), indium aluminum nitride (InAlN), boron aluminum nitride (BAlN), or boron gallium nitride (BGaN). In the embodiment illustrated in FIG. 2C, the first III-nitride ternary alloy layer 205C is indium aluminum nitride (InAlN) and the second III-nitride ternary alloy layer 210C is indium gallium nitride (InGaN), aluminum gallium nitride (AlGaN), boron aluminum nitride (BAlN), or boron gallium nitride (BGaN). In the embodiment illustrated in FIG. 2D, the first III-nitride ternary alloy layer 205D is boron aluminum nitride (BAlN) and the second III-nitride ternary alloy layer 210D is indium gallium nitride (InGaN), indium aluminum nitride (InAlN), aluminum gallium nitride (AlGaN), or boron gallium nitride (BGaN). In the embodiment illustrated in FIG. 2E, the first III-nitride ternary alloy layer 205E is boron gallium nitride (BGaN) and the second III-nitride ternary alloy layer 210E is indium gallium nitride (InGaN), indium aluminum nitride (InAlN), boron aluminum nitride (BAlN), or aluminum gallium nitride (AlGaN).

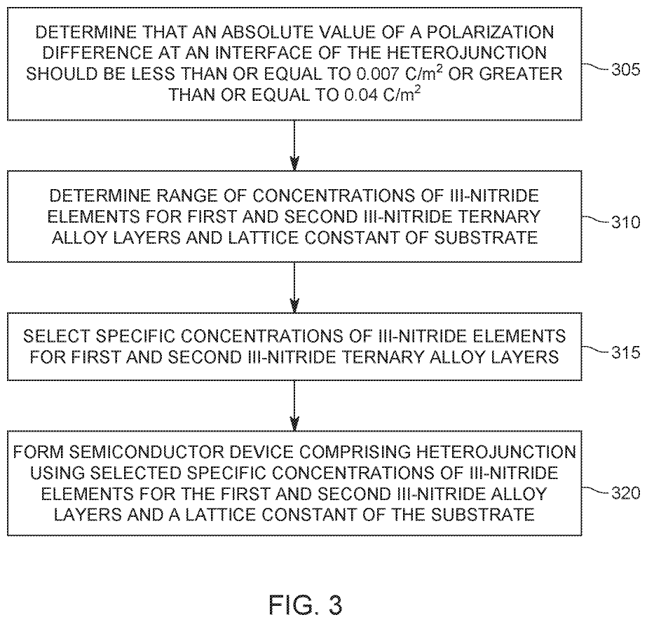

FIG. 3 is a flowchart of a method for forming a semiconductor device comprising a heterojunction of a first III-nitride ternary alloy layer arranged on a second III-nitride ternary alloy layer on a substrate. Initially, it is determined that an absolute value of a polarization difference at an interface of the heterojunction of the first and second III-nitride ternary alloy layers should be less than or equal to 0.007 C/m² or greater than or equal to 0.04 C/m² (step 305). Next, a range of concentrations of III-nitride elements for the first and second III-nitride ternary alloy layers and a lattice constant of the substrate is determined so that the absolute value of the polarization difference at the interface of the heterojunction of the first and second III-nitride ternary alloy layers is less than or equal to 0.007 C/m² or greater than or equal to 0.04 C/m² (step 310).

Specific concentrations of III-nitride elements for the first and second III-nitride ternary alloy layers are selected from the determined range of concentrations and a specific substrate is selected so that the absolute value of the polarization difference at the interface of the heterojunction of the first and second III-nitride ternary alloy layers is less than or equal to 0.007 C/m² or greater than or equal to 0.04 C/m² (step 315). The semiconductor device is then formed comprising the heterojunction on the substrate using the selected specific concentrations of III-nitride elements for the first and second III-nitride ternary alloy layers and the specific substrate (step 320). The first and second III-nitride ternary alloy layers have a wurtzite crystal structure. In one embodiment, the first III-nitride ternary alloy layer is aluminum gallium nitride (AlGaN) and the second III-nitride ternary alloy layer is indium gallium nitride (InGaN), indium aluminum nitride (InAlN), boron aluminum nitride (BAlN), or boron gallium nitride (BGaN). In another embodiment, the first III-nitride ternary alloy layer is indium gallium nitride (InGaN) and the second III-nitride ternary alloy layer is aluminum gallium nitride (AlGaN), indium aluminum nitride (InAlN), boron aluminum nitride (BAlN), or boron gallium nitride (BGaN). In a further embodiment, the first III-nitride ternary alloy layer is indium aluminum nitride (InAlN) and the second III-nitride ternary alloy layer is indium gallium nitride (InGaN), aluminum gallium nitride (AlGaN), boron aluminum nitride (BAlN), or boron gallium nitride (BGaN). In yet another embodiment, the first III-nitride ternary alloy layer is boron aluminum nitride (BAlN) and the second III-nitride ternary alloy layer is indium gallium nitride (InGaN), indium aluminum nitride (InAlN), aluminum gallium nitride (AlGaN), or boron gallium nitride (BGaN). In a further embodiment, the first III-nitride ternary alloy layer is boron gallium nitride (BGaN) and the second III-nitride ternary alloy layer is indium gallium nitride (InGaN), indium aluminum nitride (InAlN), boron aluminum nitride (BAlN), or aluminum gallium nitride (AlGaN).

The formation of the layers can be performed using any technique, including, but not limited to, metalorganic chemical vapor deposition, molecular beam epitaxy, and high temperature post-deposition annealing.

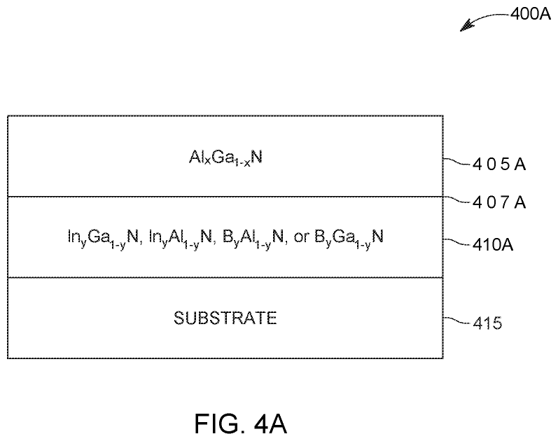

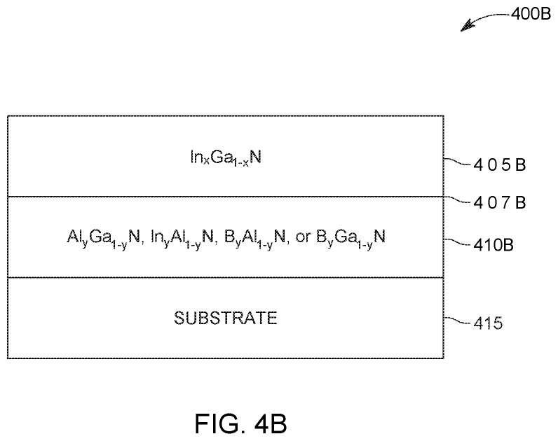

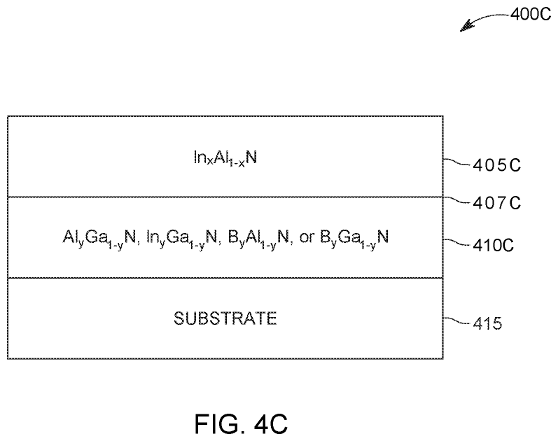

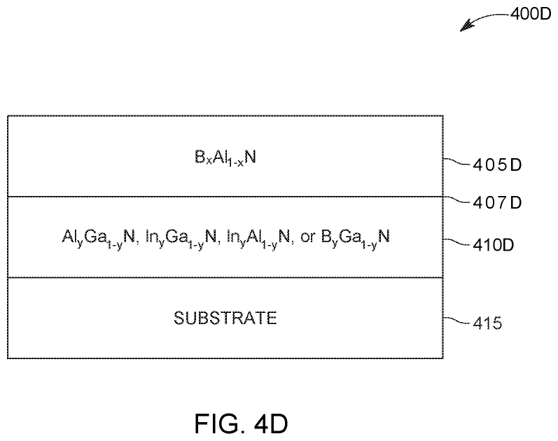

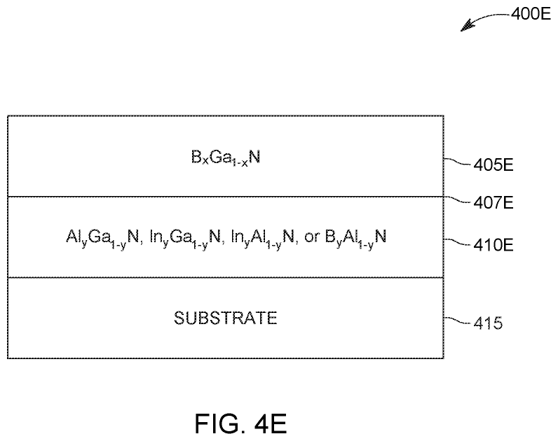

Schematic diagrams of semiconductor devices comprising a heterojunction of two wurtzite III-nitride ternary alloy layers on a substrate according to the method of FIG. 3 are illustrated in FIGS. 4A-4E. As illustrated, a heterojunction comprising a first III-nitride ternary alloy layer 405A-405E is arranged on a second III-nitride ternary alloy layer 410A-410E. A substrate 415 is arranged beneath the second III-nitride ternary alloy layer 410A-410E. An absolute value of a polarization difference at an interface 407A-407E of the heterojunction of the first 405A-405E and second 410A-410E III-nitride ternary alloy layers is less than or equal to 0.007 C/m² or greater than or equal to 0.04 C/m² based on concentrations of III-nitride elements of the first 405A-405E and second 410A-410E III-nitride ternary alloy layers and a lattice constant of the substrate 415. The first 405A-405E and second 410A-410E III-nitride ternary alloy layers have a wurtzite crystal structure. In the embodiment of FIG. 4A, the first III-nitride ternary alloy layer 405A is aluminum gallium nitride (AlGaN) and the second III-nitride ternary alloy layer 410A is indium gallium nitride (InGaN), indium aluminum nitride (InAlN), boron aluminum nitride (BAlN), or boron gallium nitride (BGaN). In the embodiment of FIG. 4B, the first III-nitride ternary alloy layer 405B is indium gallium nitride (InGaN) and the second III-nitride ternary alloy layer 410B is aluminum gallium nitride (AlGaN), indium aluminum nitride (InAlN), boron aluminum nitride (BAlN), or boron gallium nitride (BGaN). In the embodiment of FIG. 4C, the first III-nitride ternary alloy layer 405C is indium aluminum nitride (InAlN) and the second III-nitride ternary alloy layer 410C is indium gallium nitride (InGaN), aluminum gallium nitride (AlGaN), boron aluminum nitride (BAlN), or boron gallium nitride (BGaN). In the embodiment of FIG. 4D, the first III-nitride ternary alloy layer 405D is boron aluminum nitride (BAlN) and the second III-nitride ternary alloy layer 410D is indium gallium nitride (InGaN), indium aluminum nitride (InAlN), aluminum gallium nitride (AlGaN), or boron gallium nitride (BGaN). In the embodiment of FIG. 4E, the first III-nitride ternary alloy layer 405E is boron gallium nitride (BGaN) and the second III-nitride ternary alloy layer 410E is indium gallium nitride (InGaN), indium aluminum nitride (InAlN), boron aluminum nitride (BAlN), or aluminum gallium nitride (AlGaN).

The substrate 415 can be any type of substrate having a lattice constant so that, in combination with the concentrations of III-nitride elements of the first 405A-405E and second 410A-410E III-nitride ternary alloy layers, achieves an absolute value of a polarization difference at an interface 407A-407E of the heterojunction of the first 405A-405E and second 410A-410E III-nitride ternary alloy layers that is less than or equal to 0.007 C/m² or greater than or equal to 0.04 C/m². For example, the substrate 415 can be a silicon substrate, a sapphire substrate, a III-nitride binary substrate. The substrate 415 can also be a III-nitride ternary or quaternary alloy virtual substrate with relaxed or partially relaxed lattice constant grown on another substrate.

As discussed above, the range of compositions of the first and second III-nitride ternary alloy layers is based on the polarization difference at the interface between the two layers. Assuming that the first III-nitride ternary alloy layer has a composition AₓC₁₋ₓN, the second III-nitride ternary alloy layer has a composition D_{y}E_{1-y}N, and the first III-nitride ternary alloy layer is arranged on top of the second III-nitride ternary alloy layer, the polarization difference at the interface of the first and second III-nitride ternary alloy layers can be calculated as follows:

ΔP(x,y)=P(AₓC₁₋ₓN)−P(D_{y}E_{1-y}N) (1)

where P(AₓC₁₋ₓN) is the polarization of the first III-nitride ternary alloy layer and P(D_{y}E_{1-y}N) is the polarization of the second III-nitride ternary alloy layer.

The polarization of each layer is based on a sum of the spontaneous polarization (SP) of the layer and the piezoelectric polarization (PZ) of the layer:

P(AₓC₁₋ₓN)=P_{SP}(x)+P_{PZ}(x) (2)

P(D_{y}E_{1-y}N)=P_{SP}(Y)+P_{PZ}(y) (3)

where x is the percentage of composition of element A relative to element C in the upper III-nitride ternary alloy layer of the heterojunction and y is the percentage of composition of element D relative element E in the lower III-nitride ternary alloy layer of the heterojunction.

More specifically, the polarization of each layer is:

$$\begin{matrix}P ( {A}_{x} {C}_{1 - x} N ) = {P}_{S P} ( x ) + 2 [ {e}_{31} ( x ) - {P}_{S P} ( x ) - \frac{{C}_{13} ( x )}{{C}_{33} ( x )} {e}_{33} ( x ) ] \times \frac{a ( x ) - {a}_{τ e l a x} ( x )}{{a}_{τ e l a x} ( x )} & ( 4 ) \\ P ( {D}_{y} {E}_{1 - y} N ) = {P}_{S P} ( y ) + 2 [ {e}_{31} ( y ) - {P}_{S P} ( y ) - \frac{{C}_{13} ( y )}{{C}_{33} ( y )} {e}_{33} ( y ) ] \times \frac{a ( y ) - {a}_{τ e l a x} ( y )}{{a}_{τ e l a x} ( y )} & ( 5 )\end{matrix}$$

where e₃₁ is the internal-strain term of the piezoelectric constant, e₃₃ is the clamped-ion term of the piezoelectric constant (which is determined using the internal parameter μ fixed), e₃₁(x) and e₃₃(x) are the piezoelectric constants of the upper III-nitride ternary alloy layer of the heterojunction in units of C/m², e₃₁(y) and e₃₃(y) are the piezoelectric constants of the lower III-nitride ternary alloy layer of the heterojunction in units of C/m², C₁₃(x) and C₃₃(x) are the elastic constants of the upper III-nitride ternary alloy layer of the heterojunction in units of GPa, C₁₃(y) and C₃₃(y) are the elastic constants of the lower III-nitride ternary alloy layer of the heterojunction in units of GPa, α(x) is the lattice constant of the AₓC₁₋ₓN layer in units of Å, and α(y) is the lattice constant of the D_{y}E_{1-y}N layer in units of Å, αᵣₑₗₐₓ(x) is the fully-relaxed lattice constant of the AₓC₁_ₓN layer in units of Å, and αᵣₑₗₐₓ(y) is the fully-relaxed lattice constant of the D_{y}E_{1-y}N layer in units Å.

It should be recognized that when the lower III-nitride ternary alloy layer of the heterojunction is the substrate or fully relaxed on a substrate, the lower III-nitride ternary alloy layer of the heterojunction will not exhibit piezoelectric polarization because the term

$$\frac{a ( y ) - {a}_{relax} ( y )}{{a}_{relax} ( y )}$$

becomes zero. Further, when the lower III-nitride ternary alloy layer of the heterojunction is fully strained on a substrate, the lattice constant of both layers is equal to the lattice constant of the substrate. When the lower III-nitride ternary alloy layer of the heterojunction is neither fully relaxed nor fully strained on the substrate, the lattice constants of both the upper and lower III-nitride ternary alloy layers are influenced by the lattice constant of the substrate. Determination of the lattice constant of the upper and lower III-nitride ternary alloy layers when the lower III-nitride ternary alloy layer of the heterojunction is neither fully relaxed nor fully strained on the substrate can be based on experiments using, for example, x-ray diffraction (XRD) imaging. This would involve routine experimentation for one of ordinary skill in the art.

The spontaneous polarization of an aluminum gallium nitride (AlGaN) layer is:

Pₛₚ^{(H Ref)}(AlₓGa₁₋ₓN)=0.0072x²−0.0127x+1.3389 (6)

The spontaneous polarization of an indium gallium nitride (InGaN) layer is:

Pₛₚ^{(H Ref)}(InₓGa₁₋ₓN)=0.1142x²−0.2892x+1.3424 (7)

The spontaneous polarization of an indium aluminum nitride (InAlN) layer is:

Pₛₚ^{(H Ref)}(InₓAl₁₋ₓN)=0.1563x²−0.3323x+1.3402 (8)

The spontaneous polarization of a boron aluminum nitride (BAlN) layer is:

Pₛₚ^{(H Ref)}(BₓAl₁₋ₓN)=0.6287x²+0.1217x+1.3542 (9)

The spontaneous polarization of a boron gallium nitride (BGaN) layer is:

Pₛₚ^{(H Ref)}(BₓGa₁₋ₓN)=0.4383x²+0.3135x+1.3544 (10)

It should be recognized that the x subscript in formulas (6)-(10) will be a y subscript if the layer is the lower layer of the III-nitride ternary alloy heterojunction.

As indicated by formulas (4) and (5) above, the determination of the piezoelectric polarization requires the piezoelectric constants e₃₁ and e₃₃. Due to the lattice mismatch, piezoelectric polarization can be induced by applied strain (ϵ₃ or ϵ₁) and crystal deformation, which is characterized by mainly two piezoelectric constants, e₃₃ and e₃₁, given by the following equations:

$$\begin{matrix}{e}_{33} = {e}_{33}^{( 0 )} + {e}_{33}^{( IS )} = \frac{\partial {P}_{3}}{\partial {ϵ}_{3}} {\vert}_{u} + \frac{\partial {P}_{3}}{\partial u} {\vert}_{{ϵ}_{3}} \frac{du}{d {ϵ}_{3}} = {e}_{33}^{( 0 )} + \frac{2 e}{{a}^{2}} {Z}^{*} \frac{du}{d {ϵ}_{3}} , & ( 11 ) \\ {e}_{31} = {e}_{31}^{( 0 )} + {e}_{31}^{( IS )} = \frac{\partial {P}_{3}}{\partial {ϵ}_{1}} {\vert}_{u} + \frac{\partial {P}_{3}}{\partial u} {\vert}_{{ϵ}_{1}} \frac{du}{d {ϵ}_{1}} = {e}_{31}^{( 0 )} + \frac{2 e}{{a}^{2}} {Z}^{*} \frac{du}{d {ϵ}_{1}} . & ( 12 )\end{matrix}$$

The piezoelectric constants, also referred to as the relaxed terms, comprise two parts: e₃₃⁽⁰⁾ is the clamped-ion term obtained with the fixed internal parameter u; and e₃₁^{(IS)} is the internal-strain term from the bond alteration with external strain. P₃ is the macroscopic polarization along the c-axis, u is the internal parameter, Z* is the zz component of the Born effective charge tensor, e is the electronic charge, and a is the a lattice constant.

The piezoelectric constants e₃₁ and e₃₃ of an aluminum gallium nitride (AlGaN) layer are:

e₃₁(AlₓGa₁₋ₓN)=−0.0573x²−0.2536x−0.3582 (13)

e₃₃(AlₓGa₁₋ₓN)=0.3949x²+0.6324x+0.6149 (14)

The piezoelectric constants e₃₁ and e₃₃ of an indium gallium nitride (InGaN) layer are:

e₃₁(InₓGa₁₋ₓN)=0.2396x²−0.4483x−0.3399 (15)

e₃₃(InₓGa₁₋ₓN)=−0.1402x²+0.5902x+0.6080 (16)

The piezoelectric constants e₃₁ and e₃₃ of an indium aluminum nitride (InAlN) layer are:

e₃₁(InₓAl₁₋ₓN)=−0.0959x²+0.239x−0.6699 (17)

e₃₃(InₓAl₁₋ₓN)=0.9329x²−1.5036x+1.6443 (18)

The piezoelectric constants e₃₁ and e₃₃ of a boron aluminum nitride (BAlN) layer are:

e₃₁(BₓAl₁₋ₓN)=1.7616x²−0.9003x−0.6016 (19)

e₃₃(BₓAl₁₋ₓN)=−4.0355x²+1.6836x+1.5471 (20)

The piezoelectric constants e₃₁ and e₃₃ of boron gallium nitride (BGaN) layer are:

e₃₁(BₓGa₁₋ₓN)=0.9809x²−0.4007x−0.3104 (21)

e₃₃(BₓGa₁₋ₓN)=−2.1887x²+0.8174x+0.5393 (22)

It should be recognized that the x subscript in formulas (13)-(22) will be a y subscript if the layer is the lower layer of the III-nitride ternary alloy heterojunction.

As indicated by formulas (4) and (5) above, the determination of the piezoelectric polarization also requires the elastic constants C₁₃ and C₃₃ of the upper and lower III-nitride ternary alloy layer of the heterojunction. These elastic constants can be determined using the Vegard's law and the binary constants as follows. They can also be obtained by direct calculation of the ternary constants.

C₁₃(BₓAl₁₋ₓN)=xC₁₃(BN)+(1−x)C₁₃(AlN) (23)

C₃(BₓGa₁₋ₓN)=xC₁₃(BN)+(1−x)C₁₃(GaN) (24)

C₁₃(AlₓGa₁₋ₓN)=xC₁₃(AlN)+(1−x)C₁₃(GaN) (25)

C₁₃(InₓGa₁₋ₓN)=xC₁₃(InN)+(1−x)C₁₃(GaN) (26)

C₁₃(InₓAl₁₋ₓN)=xC₁₃(InN)+(1−x)C₁₃(AlN) (27)

C₃₃(BₓAl₁₋ₓN)=xC₃₃(BN)+(1−x)C₃₃(AlN) (28)

C₃₃(BₓGa₁₋ₓN)=xC₃₃(BN)+(1−x)C₃₃(GaN) (29)

C₃₃(AlₓGa₁₋ₓN)=xC₃₃(AlN)+(1−x)C₃₃(GaN) (30)

C₃₃(InₓGa₁₋ₓN)=xC₃₃(InN)+(1−x)C₃₃(GaN) (31)

C₃₃(InₓA₁₋ₓN)=xC₃₃(InN)+(1−x)C₃₃(AlN) (32)

As indicated by formulas (4) and (5) above, the determination of the piezoelectric polarization further requires the lattice constants α of the upper and lower III-nitride ternary alloy layer of the heterojunction. For ternary alloys, the cations are randomly distributed among cation sites while anion sites are always occupied by nitrogen atoms. It has been experimentally observed that there are different types of ordering in III-nitride ternary alloys.

A previous study on spontaneous polarization and piezoelectric constants of conventional III-nitride ternary alloys including AlGaN, InGaN, and AlInN shows that the spontaneous polarization from supercells with different orderings of cation atoms can differ considerably. The special quasi-random structure (SQS) can efficiently represent the microscopic structure of a random alloy in periodic conditions. However, the special quasi-random structure only applies to ternary alloys with two cations having equal composition (i.e., 50% each). On the other hand, the chalchopyritelike (CH) structure, which is defined by two cations of one species and two cations of the other species surrounding each anion (hence 50%), and the luzonitelike structure (LZ), which is defined by three cations of one species and one cation of the other species surrounding each anion (hence 25% or 75%), can well represent the microscopic structure of a random alloy for the calculation of the spontaneous polarization and piezoelectric constants. The 16-atom supercells of the chalchopyrite-like (50%) and luzonite-like (25%, 75%) structures were adopted. The lattice constants of the III-nitride ternary alloys were then calculated using III-nitride element compositions of the 0, 25%, 50% and 100% as follows:

α(BₓAl₁₋ₓN)=−0.157x²−0.408x+3.109 (Å) (33)

α(BₓGa₁₋ₓN)=−0.101x²−0.529x+3.176(Å) (34)

α(InₓAl₁₋ₓN)=0.05298x²+0.37398x+3.109 (Å) (35)

α(AlₓGa₁₋ₓN)=0.01589x²−0.08416x+3.182 (Å) (36)

α(InₓGa₁₋ₓN)=0.012x²+0.34694x+3.182 (Å) (37)

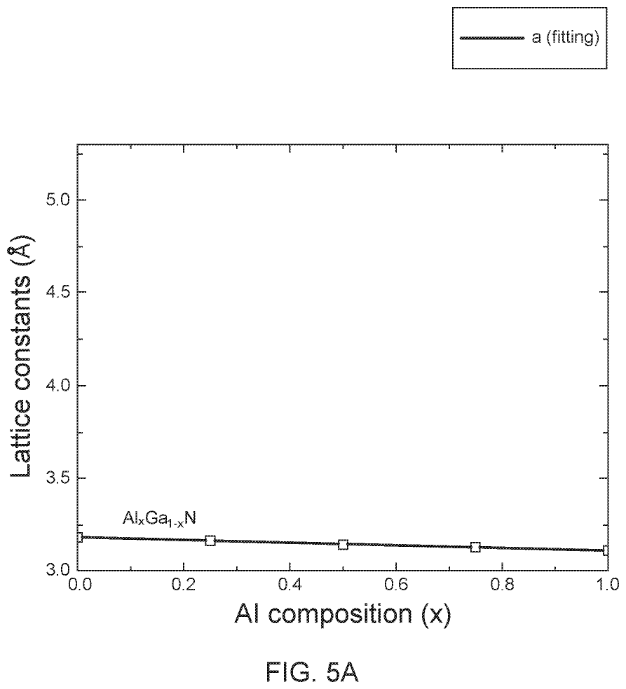

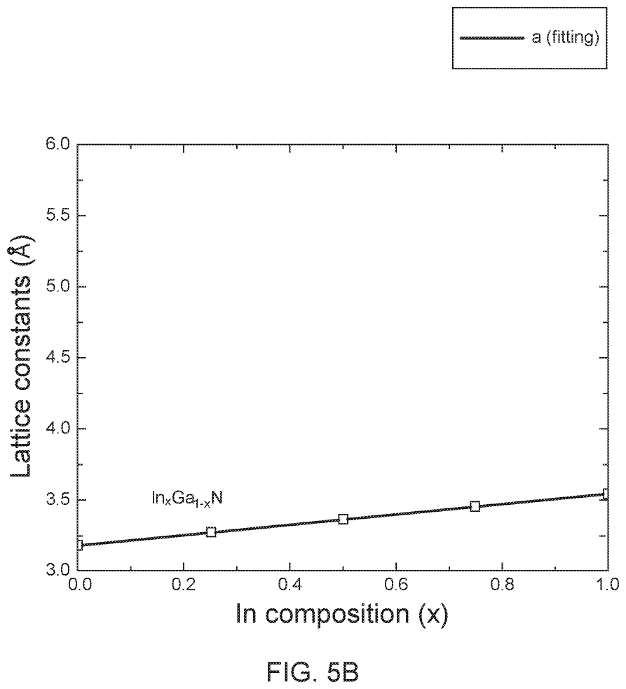

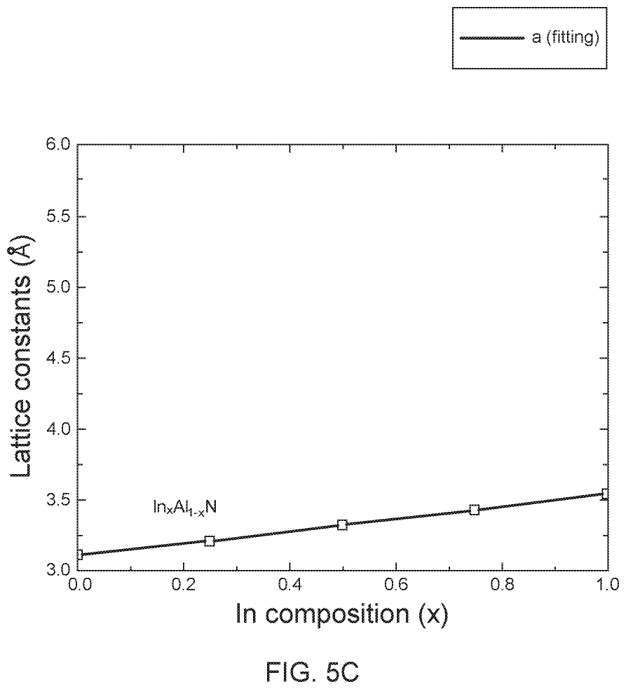

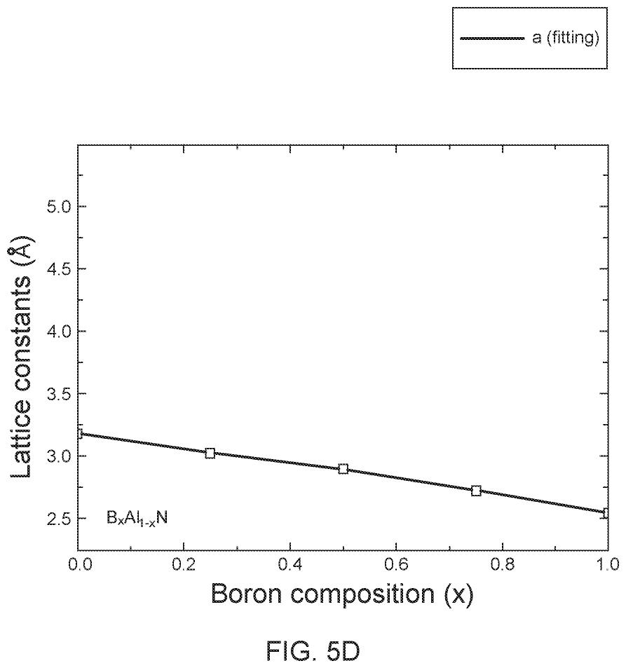

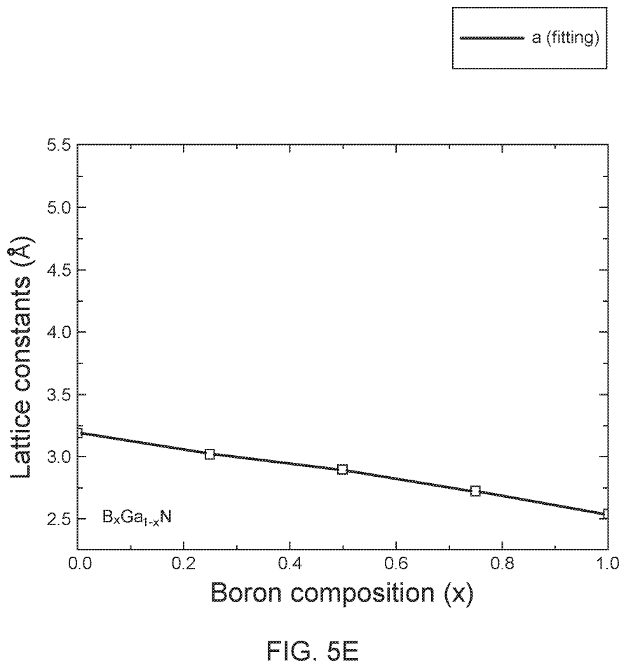

Quadratic regression was used to determine the remaining values of the lattice constants for the four different composition percentages of the III-nitride elements, the results of which are illustrated in FIGS. 5A-5E. Specifically, FIGS. 5A-5E illustrate respectively illustrate the lattice constant (a) versus concentration of the III-nitride elements for an aluminum gallium nitride (AlGaN) layer, an indium gallium nitride (InGaN) layer, indium aluminum nitride (InAlN) layer, boron aluminum nitride (BAlN) layer, and boron gallium nitride (BGaN) layer, where the layers are in a fully relaxed condition. It should be recognized that the values “a” in FIGS. 5A-5E correspond to “a” in equations (4) and (5) above.

The equations above for calculating the polarization difference at the interface of the heterojunction of the first and second III-nitride ternary alloy layers assumes the interface of the heterojunction is a sharp and clear boundary. Although there may not be a perfectly sharp and clear boundary at the interface of the heterojunction in practice, it is common practice to assume a sharp and clear boundary at the interface to calculate the polarization differences at interfaces of heterojunction of two layers. A non-sharp boundary at the interface of the heterojunction will act as an additive or subtractive factor in the polarization difference calculation. Nonetheless, because disclosed embodiments provide ranges of concentrations of III-nitride elements from which specific concentrations of III-nitride elements can be selected, one can use the disclosed embodiments to select specific concentrations that are further from the boundary conditions (i.e., closer to zero than 0.007 C/m² when a small polarization difference is desired and a higher value than 0.04 C/m² when a large polarization difference is desired) to counteract the influence of a non-sharp boundary at the interface of the heterojunction.

As noted above, conventional polarization constants used to determine the polarization difference at the interface of a heterojunction of two III-nitride ternary alloy layers having wurtzite structures were based on linear interpolation of the III-nitride binary elements, which may not be accurate. Thus, the conventional techniques may indicate, based the calculations using these interpolated polarization constants, that the interface between two III-nitride ternary alloy layers have a particular polarization difference when in fact a semiconductor device built using the calculated values can exhibit a different polarization difference at the heterojunction interface.

Using the formulas disclosed herein, a more accurate determination of the polarization difference can be determined for any composition of layers including an AlGaN layer, InGaN layer, InAlN layer, BAlN layer, and/or BGaN layer. Specifically, these formulas allow for the first time the ability to identify a range of compositions of III-nitride elements in the aforementioned III-nitride ternary alloy layers to achieve either a low polarization difference (i.e., less than or equal to 0.007 C/m²), which is useful for optoelectronic devices or a high polarization difference (i.e., greater than or equal to 0.04 C/m²), which is useful for high electron mobility transistors. The determined ranges of compositions of III-nitride elements provides great flexibility to select the specific compositions of the III-nitride elements to achieve the desired polarization difference. For example, some of the composition values in the range of compositions may not be practical for actually forming the layer with the wurtzite structure, such as a high concentration of boron, which is very difficult to form in practice. Thus, one can select a different concentration of boron in this example and adjust the concentration of the III-nitride elements in the other layer to maintain the desired polarization difference at the heterojunction interface. In contrast, prior to this disclosure, achieving a high or low polarization difference at the interface of a heterojunction of III-nitride ternary alloy layers was a best a trial and error process of adjusting the compositions of the two III-nitride ternary alloy layers in order to achieve the desired polarization difference.

The discussion above is with respect to certain III-nitride ternary alloys. It should be recognized that this is intended to cover both alloys with two III-nitride elements, as well alloys having additional elements that may arise in insignificant concentrations due to, for example, contaminants or impurities becoming part of one or both layers during the process of forming the layers. These contaminants or impurities typically comprise less than 0.1% of the overall composition of the III-nitride ternary alloy layer. Further, those skilled in the art would also consider a III-nitride alloy as a ternary alloy when, in addition to two group III elements, there is an insubstantial amount of other elements, including other group III elements. Those skilled in the art would consider a concentration of 0.1% or less of an element being an insubstantial amount. Thus, for example, one skilled in the art would consider a layer comprising AlₓGa_{1-x-y}In_{y}N, where y≤0.1%, as a ternary alloy because it includes an insubstantial amount of indium.

The disclosed embodiments provide semiconductor devices comprising a heterojunction of wurtzite III-nitride ternary alloys and methods for forming such semiconductor devices. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

What is claimed is:

1. A method for forming a semiconductor device comprising a heterojunction of a first III-nitride ternary alloy layer arranged on a second III-nitride ternary alloy layer, the method comprising:
determining that an absolute value of a polarization difference at an interface of the heterojunction of the first and second III-nitride ternary alloy layers should be less than or equal to 0.007 C/m² or greater than or equal to 0.04 C/m²;
determining a range of concentrations of III-nitride elements for the first and second III-nitride ternary alloy layers so that the absolute value of the polarization difference at the interface of the heterojunction of the first and second III-nitride ternary alloy layers is less than or equal to 0.007 C/m² or greater than or equal to 0.04 C/m²;
selecting, from the determined range of concentrations, specific concentrations of III-nitride elements for the first and second III-nitride ternary alloy layers so that the absolute value of the polarization difference at the interface of the heterojunction of the first and second III-nitride ternary alloy layers is less than or equal to 0.007 C/m² or greater than or equal to 0.04 C/m²; and
forming the semiconductor device comprising the heterojunction using the selected specific concentrations of III-nitride elements for the first and second III-nitride ternary alloy layers,
wherein the first and second III-nitride ternary alloy layers have a wurtzite crystal structure, and
wherein
the first III-nitride ternary alloy layer is aluminum gallium nitride, AlGaN, and the second III-nitride ternary alloy layer is indium gallium nitride, InGaN, indium aluminum nitride, InAlN, boron aluminum nitride, BAlN, or boron gallium nitride, BGaN,
the first III-nitride ternary alloy layer is indium gallium nitride, InGaN, and the second III-nitride ternary alloy layer is aluminum gallium nitride, AlGaN, indium aluminum nitride, InAlN, boron aluminum nitride, BAlN, or boron gallium nitride, BGaN,
the first III-nitride ternary alloy layer is indium aluminum nitride, InAlN, and the second III-nitride ternary alloy layer is indium gallium nitride, InGaN, aluminum gallium nitride, AlGaN, boron aluminum nitride, BAlN, or boron gallium nitride, BGaN,
the first III-nitride ternary alloy layer is boron aluminum nitride, BAlN, and the second III-nitride ternary alloy layer is indium gallium nitride, InGaN, indium aluminum nitride, InAlN, aluminum gallium nitride, AlGaN, or boron gallium nitride, BGaN, or
the first III-nitride ternary alloy layer is boron gallium nitride, BGaN, and the second III-nitride ternary alloy layer is indium gallium nitride, InGaN, indium aluminum nitride, InAlN, boron aluminum nitride, BAlN, or aluminum gallium nitride, AlGaN.

2. The method of claim 1, further comprising:
determining the range of concentrations of III-nitride elements for the first and second III-nitride ternary alloy layers based on a sum of a spontaneous polarization and a piezoelectric polarization of the first III-nitride ternary alloy layer and based on a sum of a spontaneous polarization and a piezoelectric polarization of the second III-nitride ternary alloy layer.

3. The method of claim 2, wherein
the first III-nitride ternary alloy layer comprises AlₓGa₁₋ₓN,
the second III-nitride ternary alloy layer comprises In_{y}Ga_{1-y}N,
the spontaneous polarization of the first III-nitride ternary alloy layer is in units of C/m² and is equal to 0.0072x²−0.0127x+1.3389, and
the spontaneous polarization of the second III-nitride ternary alloy layer is in units of C/m² and is equal to 0.1142y²−0.2892y+1.3424.

4. The method of claim 3, wherein
the piezoelectric polarization of the first III-nitride ternary alloy layer is
$$2 [ {e}_{31} ( x ) - {P}_{S P} ( x ) - \frac{{C}_{13} ( x )}{{C}_{33} ( x )} {e}_{33} ( x ) ] \times \frac{a ( x ) - {a}_{relax} ( x )}{{a}_{relax} ( x )} ,$$
the piezoelectric polarization of the second III-nitride ternary alloy layer is
$$2 [ {e}_{31} ( y ) - {P}_{S P} ( y ) - \frac{{C}_{13} ( y )}{{C}_{33} ( y )} {e}_{33} ( y ) ] \times \frac{a ( y ) - {a}_{relax} ( y )}{{a}_{relax} ( y )} ,$$
e₃₁(x) is an internal-strain term of a piezoelectric constant of the first III-nitride ternary alloy layer in units of C/m² and is equal to −0.0573x²−0.2536x−0.3582,
e₃₃(x) is a clamped-ion term of the piezoelectric constant of the first III-nitride ternary alloy layer in units of C/m² and is equal to 0.3949x²+0.6324x+0.6149,
e₃₁(y) is an internal-strain term of a piezoelectric constant of the second III-nitride ternary alloy layer in units of C/m² and is equal to 0.2396y²−0.4483y−0.3399,
e₃₃(y) is a clamped-ion term of the piezoelectric constant of the second III-nitride ternary alloy layer in units of C/m² and is equal to −0.1402y²+0.5902y+0.6080,
α(x) is in units of Å and is a lattice constant of the first III-nitride ternary alloy layer,
α(y) is in units of Å and is a lattice constant of the second aluminum nitride ternary alloy layer,
αᵣₑₗₐₓ(x) in units of Å and is a fully-relaxed lattice constant of the first III-nitride ternary alloy layer,
αᵣₑₗₐₓ(y) in units of Å and is a fully-relaxed lattice constant of the second III-nitride ternary alloy layer,
C₁₃(x) and C₃₃(x) are in units of GPa and are elastic constants of the first III-nitride ternary alloy layer,
C₁₃(y) and C₃₃(y) are in units of GPa and are elastic constants of the second III-nitride ternary alloy layer,
P_{SP}(x) is the spontaneous polarization of the first III-nitride ternary alloy layer, and
P_{SP}(y) is the spontaneous polarization of the second III-nitride ternary alloy layer.

5. The method of claim 2, wherein
the first III-nitride ternary alloy layer comprises AlₓGa₁₋ₓN,
the second III-nitride ternary alloy layer comprises In_{y}Al_{1-y}N,
the spontaneous polarization of the first III-nitride ternary alloy layer is in units of C/m² and is equal to 0.0072x²−0.01 27x+1.3389, and
the spontaneous polarization of the second III-nitride ternary alloy layer is in units of C/m² and is equal to 0.1563y²− 0.3323y+1.3402.

6. The method of claim 5, wherein
the piezoelectric polarization of the first III-nitride ternary alloy layer is
$$2 [ {e}_{31} ( x ) - {P}_{S P} ( x ) - \frac{{C}_{13} ( x )}{{C}_{33} ( x )} {e}_{33} ( x ) ] \times \frac{a ( x ) - {a}_{relax} ( x )}{{a}_{relax} ( x )} ,$$
the piezoelectric polarization of the second III-nitride ternary alloy layer is
$$2 [ {e}_{31} ( y ) - {P}_{S P} ( y ) - \frac{{C}_{13} ( y )}{{C}_{33} ( y )} {e}_{33} ( y ) ] \times \frac{a ( y ) - {a}_{relax} ( y )}{{a}_{relax} ( y )} ,$$
e₃₁(x) is an internal-strain term of a piezoelectric constant of the first III-nitride ternary alloy layer in units of C/m² and is equal to −0.0573x²−0.2536x−0.3582,
e₃₃(x) is a clamped-ion term of the piezoelectric constant of the first III-nitride ternary alloy layer in units of C/m² and is equal to 0.3949x²+0.6324x+0.6149,
e₃₁(y) is an internal-strain term of a piezoelectric constant of the second III-nitride ternary alloy layer in units of C/m² and is equal to −0.0959y²+0.239y−0.6699,
e₃₃(y) is a clamped-ion term of the piezoelectric constant of the second III-nitride ternary alloy layer in units of C/m² and is equal to 0.9329y²−1.5036y+1.6443,
α(x) is in units of Å and is a lattice constant of the first III-nitride ternary alloy layer,
α(y) is in units of Å and is a lattice constant of the second aluminum nitride ternary alloy layer,
αᵣₑₗₐₓ(x) is in units of Å and is a fully-relaxed lattice constant of the first III-nitride ternary alloy layer,
αᵣₑₗₐₓ(y) is in units of Å and is a fully-relaxed lattice constant of the second III-nitride ternary alloy layer,
C₁₃(x) and C₃₃(x) are in units of GPa and are elastic constants of the first III-nitride ternary alloy layer,
C₁₃(y) and C₃₃(y) are in units of GPa and are elastic constants of the second III-nitride ternary alloy layer,
P_{SP}(x) is the spontaneous polarization of the first III-nitride ternary alloy layer, and
P_{SP}(y) is the spontaneous polarization of the second III-nitride ternary alloy layer.

7. The method of claim 2, wherein
the first III-nitride ternary alloy layer comprises AlₓGa₁₋ₓN,
the second III-nitride ternary alloy layer comprises B_{y}Al_{1-y}N,
the spontaneous polarization of the first III-nitride ternary alloy layer is in units of C/m² and is equal to 0.0072x²−0.0127x+1.3389, and
the spontaneous polarization of the second III-nitride ternary alloy layer is in units of C/m² and is equal to 0.6287y²+0.1217y+1.3542.

8. The method of claim 7, wherein
the piezoelectric polarization of the first III-nitride ternary alloy layer is
$$2 [ {e}_{31} ( x ) - {P}_{S P} ( x ) - \frac{{C}_{13} ( x )}{{C}_{33} ( x )} {e}_{33} ( x ) ] \times \frac{a ( x ) - {a}_{relax} ( x )}{{a}_{relax} ( x )} ,$$
the piezoelectric polarization of the second III-nitride ternary alloy layer is
$$2 [ {e}_{31} ( y ) - {P}_{S P} ( y ) - \frac{{C}_{13} ( y )}{{C}_{33} ( y )} {e}_{33} ( y ) ] \times \frac{a ( y ) - {a}_{relax} ( y )}{{a}_{relax} ( y )} ,$$
e₃₁(x) is an internal-strain term of a piezoelectric constant of the first III-nitride ternary alloy layer in units of C/m² and is equal to −0.0573x²−0.2536x−0.3582,
e₃₃(x) is a clamped-ion term of the piezoelectric constant of the first III-nitride ternary alloy layer in units of C/m² and is equal to 0.3949x²+0.6324x+0.6149,
e₃₁(y) is an internal-strain term of a piezoelectric constant of the second III-nitride ternary alloy layer in units of C/m² and is equal to 1.7616y²− 0.9003y−0.6016,
e₃₃(y) is a clamped-ion term of the piezoelectric constant of the second III-nitride ternary alloy layer in units of C/m² and is equal to −4.0355y²+1.6836y+1.5471,
α(x) is in units of Å and is a lattice constant of the first III-nitride ternary alloy layer,
α(y) is in units of Å and is a lattice constant of the second aluminum nitride ternary alloy layer,
αᵣₑₗₐₓ(x) is in units of Å and is a fully-relaxed lattice constant of the first III-nitride ternary alloy layer,
αᵣₑₗₐₓ(y) is in units of Å and is a fully-relaxed lattice constant of the second III-nitride ternary alloy layer,
C₁₃(x) and C₃₃(x) are in units of GPa and are elastic constants of the first III-nitride ternary alloy layer,
C₁₃(y) and C₃₃(y) are in units of GPa and are elastic constants of the second III-nitride ternary alloy layer,
P_{SP}(x) is the spontaneous polarization of the first III-nitride ternary alloy layer, and
P_{SP}(y) is the spontaneous polarization of the second III-nitride ternary alloy layer.

9. The method of claim 2, wherein
the first III-nitride ternary alloy layer comprises AlₓGa₁₋ₓN,
the second III-nitride ternary alloy layer comprises B_{y}Ga_{1-y}N,
the spontaneous polarization of the first III-nitride ternary alloy layer is in units of C/m² and is equal to 0.0072x²−0.0127x+1.3389, and
the spontaneous polarization of the second III-nitride ternary alloy layer is in units of C/m² and is equal to 0.4383y²+0.3135y+1.3544.

10. The method of claim 9, wherein
the piezoelectric polarization of the first III-nitride ternary alloy layer is
$$2 [ {e}_{31} ( x ) - {P}_{S P} ( x ) - \frac{{C}_{13} ( x )}{{C}_{33} ( x )} {e}_{33} ( x ) ] \times \frac{a ( x ) - {a}_{relax} ( x )}{{a}_{relax} ( x )} ,$$
the piezoelectric polarization of the second III-nitride ternary alloy layer is
$$2 [ {e}_{31} ( y ) - {P}_{S P} ( y ) - \frac{{C}_{13} ( y )}{{C}_{33} ( y )} {e}_{33} ( y ) ] \times \frac{a ( y ) - {a}_{relax} ( y )}{{a}_{relax} ( y )} ,$$
e₃₁(x) is an internal-strain term of a piezoelectric constant of the first III-nitride ternary alloy layer in units of C/m² and is equal to −0.0573x²−0.2536x−0.3582,
e₃₃(x) is a clamped-ion term of the piezoelectric constant of the first III-nitride ternary alloy layer in units of C/m² and is equal to 0.3949x²+0.6324x+0.6149,
e₃₁(y) is an internal-strain term of a piezoelectric constant of the second III-nitride ternary alloy layer in units of C/m² and is equal to 0.9809y²−0.4007y−0.3104,
e₃₃(y) is a clamped-ion term of the piezoelectric constant of the second III-nitride ternary alloy layer in units of C/m² and is equal to −2.1887y²+0.81 74y+0.5393,
α(x) is in units of Å and is a lattice constant of the first III-nitride ternary alloy layer,
α(y) is in units of Å and is a lattice constant of the second aluminum nitride ternary alloy layer,
αᵣₑₗₐₓ(x) is in units of Å and is a fully-relaxed lattice constant of the first III-nitride ternary alloy layer,
αᵣₑₗₐₓ(y) is in units of Å and is a fully-relaxed lattice constant of the second III-nitride ternary alloy layer,
C₁₃(x) and C₃₃(x) are in units of GPa and are elastic constants of the first III-nitride ternary alloy layer,
C₁₃(y) and C₃₃(y) are in units of GPa and are elastic constants of the second III-nitride ternary alloy layer,
P_{SP}(x) is the spontaneous polarization of the first III-nitride ternary alloy layer, and
P_{SP}(y) is the spontaneous polarization of the second III-nitride ternary alloy layer.

11. A semiconductor device, comprising:
a heterojunction comprising a first III-nitride ternary alloy layer arranged on a second III-nitride ternary alloy layer, wherein
an absolute value of a polarization difference at an interface of the heterojunction of the first and second III-nitride ternary alloy layers is less than or equal to 0.007 C/m² or greater than or equal to 0.04 C/m² based on concentrations of III-nitride elements of the first and second III-nitride ternary alloy layers,
wherein the first and second III-nitride ternary alloy layers have a wurtzite crystal structure, and wherein
the first III-nitride ternary alloy layer is aluminum gallium nitride, AlGaN, and the second III-nitride ternary alloy layer is indium gallium nitride, InGaN, indium aluminum nitride, InAlN, boron aluminum nitride, BAlN, or boron gallium nitride, BGaN,
the first III-nitride ternary alloy layer is indium gallium nitride, InGaN, and the second III-nitride ternary alloy layer is aluminum gallium nitride, AlGaN, indium aluminum nitride, InAlN, boron aluminum nitride, BAlN, or boron gallium nitride, BGaN,
the first III-nitride ternary alloy layer is indium aluminum nitride, InAlN, and the second III-nitride ternary alloy layer is indium gallium nitride, InGaN, aluminum gallium nitride, AlGaN, boron aluminum nitride, BAlN, or boron gallium nitride, BGaN,
the first III-nitride ternary alloy layer is boron aluminum nitride, BAlN, and the second III-nitride ternary alloy layer is indium gallium nitride, InGaN, indium aluminum nitride, InAlN, aluminum gallium nitride, AlGaN, or boron gallium nitride, BGaN, or
the first III-nitride ternary alloy layer is boron gallium nitride, BGaN, and the second III-nitride ternary alloy layer is indium gallium nitride, InGaN, indium aluminum nitride, InAlN, boron aluminum nitride, BAlN, or aluminum gallium nitride, AlGaN.

12. The semiconductor device of claim 11, wherein the second III-nitride ternary alloy layer is a substrate of the semiconductor device.

13. The semiconductor device of claim 11, further comprising:
a substrate on which the second III-nitride ternary layer is arranged.

14. The semiconductor device of claim 11, wherein the absolute value of the polarization difference at the interface of the heterojunction of the first and second III-nitride ternary alloy layers is less than or equal to 0.007 C/m² and the semiconductor device is an optoelectronic device.

15. The semiconductor device of claim 11, wherein the absolute value of the polarization difference at the interface of the heterojunction of the first and second III-nitride ternary alloy layers is greater than or equal to 0.04 C/m² and the semiconductor device is a high electron mobility transistor, HEMT.

16. A method for forming a semiconductor device comprising a heterojunction of a first III-nitride ternary alloy layer arranged on a second III-nitride ternary alloy layer on a substrate, the method comprising:
determining that an absolute value of a polarization difference at an interface of the heterojunction of the first and second III-nitride ternary alloy layers should be less than or equal to 0.007 C/m² or greater than or equal to 0.04 C/m²;
determining a range of concentrations of III-nitride elements for the first and second III-nitride ternary alloy layers and a lattice constant of the substrate so that the absolute value of the polarization difference at the interface of the heterojunction of the first and second III-nitride ternary alloy layers is less than or equal to 0.007 C/m² or greater than or equal to 0.04 C/m²;
selecting, from the determined range of concentrations, specific concentrations of III-nitride elements for the first and second III-nitride ternary alloy layers and selecting a specific substrate so that the absolute value of the polarization difference at the interface of the heterojunction of the first and second III-nitride ternary alloy layers is less than or equal to 0.007 C/m² or greater than or equal to 0.04 C/m²; and
forming the semiconductor device comprising the heterojunction on the substrate using the selected specific concentrations of III-nitride elements for the first and second III-nitride ternary alloy layers and the specific substrate,
wherein the first and second III-nitride ternary alloy layers have a wurtzite crystal structure, and
wherein
the first III-nitride ternary alloy layer is aluminum gallium nitride, AlGaN, and the second III-nitride ternary alloy layer is indium gallium nitride, InGaN, indium aluminum nitride, InAlN, boron aluminum nitride, BAlN, or boron gallium nitride, BGaN,
the first III-nitride ternary alloy layer is indium gallium nitride, InGaN, and the second III-nitride ternary alloy layer is aluminum gallium nitride, AlGaN, indium aluminum nitride, InAlN, boron aluminum nitride, BAlN, or boron gallium nitride, BGaN,
the first III-nitride ternary alloy layer is indium aluminum nitride, InAlN, and the second III-nitride ternary alloy layer is indium gallium nitride, InGaN, aluminum gallium nitride, AlGaN, boron aluminum nitride, BAlN, or boron gallium nitride, BGaN,
the first III-nitride ternary alloy layer is boron aluminum nitride, BAlN, and the second III-nitride ternary alloy layer is indium gallium nitride, InGaN, indium aluminum nitride, InAlN, aluminum gallium nitride, AlGaN, or boron gallium nitride, BGaN, or
the first III-nitride ternary alloy layer is boron gallium nitride, BGaN, and the second III-nitride ternary alloy layer is indium gallium nitride, InGaN, indium aluminum nitride, InAlN, boron aluminum nitride, BAlN, or aluminum gallium nitride, AlGaN.

17. The method of claim 16, further comprising:
determining the range of concentrations of III-nitride elements for the first and second III-nitride ternary alloy layers based on a sum of a spontaneous polarization and a piezoelectric polarization of the first III-nitride ternary alloy layer and based on a sum of a spontaneous polarization and a piezoelectric polarization of the second III-nitride ternary alloy layer, wherein
the first III-nitride ternary alloy layer comprises AlₓGa₁₋ₓN,
the second III-nitride ternary alloy layer comprises In_{y}Ga_{1-y}N,
the spontaneous polarization of the first III-nitride ternary alloy layer is in units of C/m² and is equal to 0.0072x²−0.0127x+1.3389,
the spontaneous polarization of the second III-nitride ternary alloy layer is in units of C/m² and is equal to 0.1142y²− 0.2892y+1.3424,
the piezoelectric polarization of the first III-nitride ternary alloy layer is
$$2 [ {e}_{31} ( x ) - {P}_{S P} ( x ) - \frac{{C}_{13} ( x )}{{C}_{33} ( x )} {e}_{33} ( x ) ] \times \frac{a ( x ) - {a}_{relax} ( x )}{{a}_{relax} ( x )} ,$$
the piezoelectric polarization of the second III-nitride ternary alloy layer is
$$2 [ {e}_{31} ( y ) - {P}_{S P} ( y ) - \frac{{C}_{13} ( y )}{{C}_{33} ( y )} {e}_{33} ( y ) ] \times \frac{a ( y ) - {a}_{relax} ( y )}{{a}_{relax} ( y )} ,$$
e₃₁(x) is an internal-strain term of a piezoelectric constant of the first III-nitride ternary alloy layer in units of C/m² and is equal to −0.0573x²−0.2536x−0.3582,
e₃₃(x) is a clamped-ion term of the piezoelectric constant of the first III-nitride ternary alloy layer in units of C/m² and is equal to 0.3949x²+0.6324x+0.6149,
e₃₁(y) is an internal-strain term of a piezoelectric constant of the second III-nitride ternary alloy layer in units of C/m² and is equal to 0.2396y²− 0.4483y−0.3399,
e₃₃(y) is a clamped-ion term of the piezoelectric constant of the second III-nitride ternary alloy layer in units of C/m² and is equal to −0.1402y²+0.5902y+0.6080,
α(x) is in units of Å and is a lattice constant of the first III-nitride ternary alloy layer,
α(y) is in units of Å and is a lattice constant of the second aluminum nitride ternary alloy layer,
αᵣₑₗₐₓ(x) is in units of Å and is a fully-relaxed lattice constant of the first III-nitride ternary alloy layer,
αᵣₑₗₐₓ(y) is in units of Å and is a fully-relaxed lattice constant of the second III-nitride ternary alloy layer,
C₁₃(x) and C₃₃(x) are in units of GPa and are elastic constants of the first III-nitride ternary alloy layer,
C₁₃(y) and C₃₃(y) are in units of GPa and are elastic constants of the second III-nitride ternary alloy layer,
P_{SP}(x) is the spontaneous polarization of the first III-nitride ternary alloy layer, and
P_{SP}(y) is the spontaneous polarization of the second III-nitride ternary alloy layer.

18. The method of claim 16, further comprising:
determining the range of concentrations of III-nitride elements for the first and second III-nitride ternary alloy layers based on a sum of a spontaneous polarization and a piezoelectric polarization of the first III-nitride ternary alloy layer and based on a sum of a spontaneous polarization and a piezoelectric polarization of the second III-nitride ternary alloy layer, wherein
the first III-nitride ternary alloy layer comprises AlₓGa₁₋ₓN,
the second III-nitride ternary alloy layer comprises In_{y}Al_{1-y}N,
the spontaneous polarization of the first III-nitride ternary alloy layer is in units of C/m² and is equal to 0.0072x²−0.0127x+1.3389,
the spontaneous polarization of the second III-nitride ternary alloy layer is in units of C/m² and is equal to 0.1563y²− 0.3323y+1.3402,
the piezoelectric polarization of the first III-nitride ternary alloy layer is
$$2 [ {e}_{31} ( x ) - {P}_{S P} ( x ) - \frac{{C}_{13} ( x )}{{C}_{33} ( x )} {e}_{33} ( x ) ] \times \frac{a ( x ) - {a}_{relax} ( x )}{{a}_{relax} ( x )} ,$$
the piezoelectric polarization of the second III-nitride ternary alloy layer is
$$2 [ {e}_{31} ( y ) - {P}_{S P} ( y ) - \frac{{C}_{13} ( y )}{{C}_{33} ( y )} {e}_{33} ( y ) ] \times \frac{a ( y ) - {a}_{relax} ( y )}{{a}_{relax} ( y )} ,$$
e₃₁(x) is an internal-strain term of a piezoelectric constant of the first III-nitride ternary alloy layer in units of C/m² and is equal to −0.0573x²−0.2536x−0.3582,
e₃₃(x) is a clamped-ion term of the piezoelectric constant of the first III-nitride ternary alloy layer in units of C/m² and is equal to 0.3949x²+0.6324x+0.6149,
e₃₁(y) is an internal-strain term of a piezoelectric constant of the second III-nitride ternary alloy layer in units of C/m² and is equal to −0.0959y²+0.239y−0.6699,
e₃₃(y) is a clamped-ion term of the piezoelectric constant of the second III-nitride ternary alloy layer in units of C/m² and is equal to 0.9329y²−1.5036y+1.6443,
α(x) is in units of Å and is a lattice constant of the first III-nitride ternary alloy layer,
α(y) is in units of Å and is a lattice constant of the second aluminum nitride ternary alloy layer,
αᵣₑₗₐₓ(x) is in units of Å and is a fully-relaxed lattice constant of the first III-nitride ternary alloy layer,
αᵣₑₗₐₓ(y) is in units of Å and is a fully-relaxed lattice constant of the second III-nitride ternary alloy layer,
C₁₃(x) and C₃₃(x) are in units of GPa and are elastic constants of the first III-nitride ternary alloy layer,
C₁₃(y) and C₃₃(y) are in units of GPa and are elastic constants of the second III-nitride ternary alloy layer,
P_{SP}(x) is the spontaneous polarization of the first III-nitride ternary alloy layer, and
P_{SP}(y) is the spontaneous polarization of the second III-nitride ternary alloy layer.

19. The method of claim 16, further comprising:
determining the range of concentrations of III-nitride elements for the first and second III-nitride ternary alloy layers based on a sum of a spontaneous polarization and a piezoelectric polarization of the first III-nitride ternary alloy layer and based on a sum of a spontaneous polarization and a piezoelectric polarization of the second III-nitride ternary alloy layer, wherein
the first III-nitride ternary alloy layer comprises AlₓGa₁₋ₓN,
the second III-nitride ternary alloy layer comprises B_{y}Al_{1-y}N,
the spontaneous polarization of the first III-nitride ternary alloy layer is in units of C/m² and is equal to 0.0072x²−0.0127x+1.3389,
the spontaneous polarization of the second III-nitride ternary alloy layer is in units of C/m² and is equal to 0.6287y²+0.1217y+1.3542,
the piezoelectric polarization of the first III-nitride ternary alloy layer is
$$2 [ {e}_{31} ( x ) - {P}_{S P} ( x ) - \frac{{C}_{13} ( x )}{{C}_{33} ( x )} {e}_{33} ( x ) ] \times \frac{a ( x ) - {a}_{relax} ( x )}{{a}_{relax} ( x )} ,$$
the piezoelectric polarization of the second III-nitride ternary alloy layer is
$$2 [ {e}_{31} ( y ) - {P}_{S P} ( y ) - \frac{{C}_{13} ( y )}{{C}_{33} ( y )} {e}_{33} ( y ) ] \times \frac{a ( y ) - {a}_{relax} ( y )}{{a}_{relax} ( y )} ,$$
e₃₁(x) is an internal-strain term of a piezoelectric constant of the first III-nitride ternary alloy layer in units of C/m² and is equal to −0.0573x²−0.2536x−0.3582,
e₃₃(x) is a clamped-ion term of the piezoelectric constant of the first III-nitride ternary alloy layer in units of C/m² and is equal to 0.3949x²+0.6324x+0.6149,
e₃₁(y) is an internal-strain term of a piezoelectric constant of the second III-nitride ternary alloy layer in units of C/m² and is equal to 1.7616y²− 0.9003y−0.6016,
e₃₃(y) is a clamped-ion term of the piezoelectric constant of the second III-nitride ternary alloy layer in units of C/m² and is equal to −4.0355y²+1.6836y+1.5471,
α(x) is in units of Å and is a lattice constant of the first III-nitride ternary alloy layer,
α(y) is in units of Å and is a lattice constant of the second aluminum nitride ternary alloy layer,
αᵣₑₗₐₓ(x) is in units of Å and is a fully-relaxed lattice constant of the first III-nitride ternary alloy layer,
αᵣₑₗₐₓ(y) is in units of Å and is a fully-relaxed lattice constant of the second III-nitride ternary alloy layer,
C₁₃(x) and C₃₃(x) are in units of GPa and are elastic constants of the first III-nitride ternary alloy layer,
C₁₃(y) and C₃₃(y) are in units of GPa and are elastic constants of the second III-nitride ternary alloy layer,
P_{SP}(x) is the spontaneous polarization of the first III-nitride ternary alloy layer, and
P_{SP}(y) is the spontaneous polarization of the second III-nitride ternary alloy layer.

20. The method of claim 16, further comprising:
determining the range of concentrations of III-nitride elements for the first and second III-nitride ternary alloy layers based on a sum of a spontaneous polarization and a piezoelectric polarization of the first III-nitride ternary alloy layer and based on a sum of a spontaneous polarization and a piezoelectric polarization of the second III-nitride ternary alloy layer, wherein
the first III-nitride ternary alloy layer comprises AlₓGa₁₋ₓN,
the second III-nitride ternary alloy layer comprises B_{y}Ga_{1-y}N,
the spontaneous polarization of the first III-nitride ternary alloy layer is in units of C/m² and is equal to 0.0072x²−0.0127x+1.3389,
the spontaneous polarization of the second III-nitride ternary alloy layer is in units of C/m² and is equal to 0.4383y²+0.3135y+1.3544,
the piezoelectric polarization of the first III-nitride ternary alloy layer is
$$2 [ {e}_{31} ( x ) - {P}_{S P} ( x ) - \frac{{C}_{13} ( x )}{{C}_{33} ( x )} {e}_{33} ( x ) ] \times \frac{a ( x ) - {a}_{relax} ( x )}{{a}_{relax} ( x )} ,$$
the piezoelectric polarization of the second III-nitride ternary alloy layer is
$$2 [ {e}_{31} ( y ) - {P}_{S P} ( y ) - \frac{{C}_{13} ( y )}{{C}_{33} ( y )} {e}_{33} ( y ) ] \times \frac{a ( y ) - {a}_{relax} ( y )}{{a}_{relax} ( y )} ,$$
e₃₁(x) is an internal-strain term of a piezoelectric constant of the first III-nitride ternary alloy layer in units of C/m² and is equal to −0.0573x²−0.2536x−0.3582,
e₃₃(x) is a clamped-ion term of the piezoelectric constant of the first III-nitride ternary alloy layer in units of C/m² and is equal to 0.3949x²+0.6324x+0.6149,
e₃₁(y) is an internal-strain term of a piezoelectric constant of the second III-nitride ternary alloy layer in units of C/m² and is equal to 0.9809y²− 0.4007y−0.3104,
e₃₃(y) is a clamped-ion term of the piezoelectric constant of the second III-nitride ternary alloy layer in units of C/m² and is equal to −2.1887y²+0.8174y+0.5393,
α(x) is in units of Å and is a lattice constant of the first III-nitride ternary alloy layer,
α(y) is in units of Å and is a lattice constant of the second aluminum nitride ternary alloy layer,
αᵣₑₗₐₓ(x) is in units of Å and is a fully-relaxed lattice constant of the first III-nitride ternary alloy layer,
αᵣₑₗₐₓ(y) is in units of Å and is a fully-relaxed lattice constant of the second III-nitride ternary alloy layer,
C₁₃(x) and C₃₃(x) are in units of GPa and are elastic constants of the first III-nitride ternary alloy layer,
C₁₃(y) and C₃₃(y) are in units of GPa and are elastic constants of the second III-nitride ternary alloy layer,
P_{SP}(x) is the spontaneous polarization of the first III-nitride ternary alloy layer, and
P_{SP}(y) is the spontaneous polarization of the second III-nitride ternary alloy layer.
